(19) United States
(12) Patent Application Publication
(10) Pub. No.: US 2025/0392802 A1
(43) Pub. Date: Dec. 25, 2025

(54) CAMERA ASSEMBLY

(71) Applicant: HANWHA VISION CO., LTD., Seongnam-si (KR)

(72) Inventors: Kil Hwa HONG, Seongnam-si (KR); Dae Kyung KIM, Seongnam-si (KR); Tae Kyun CHANG, Seongnam-si (KR); Sung Min KANG, Seongnam-si (KR)

(73) Assignee: HANWHA VISION CO., LTD., Seongnam-si (KR)

(21) Appl. No.: 19/244,611

(22) Filed: Jun. 20, 2025

(30) Foreign Application Priority Data
Jun. 21, 2024 (KR) 10-2024-0081371
May 28, 2025 (KR) 10-2025-0070014

(51) Int. Cl. H04N 23/54; H04N 7/18; H05K 1/02

(52) U.S. Cl. CPC H04N 23/54; H05K 1/0203; H04N 7/183; H05K 2201/066

(57) ABSTRACT

A camera assembly may include: a camera; a base connected to the camera; a circuit board accommodated by the base; a heat sink on the circuit board; a rubber pad between the base and the heat sink; and a first thermal pad between and in contact with the circuit board and the heat sink, wherein the circuit board is sealed from an outside of the camera assembly by the heat sink and the rubber pad.

### CROSS-REFERENCE TO RELATED APPLICATIONS

This application claims priority under 35 U.S.C. § 119 to Korean Patent Application Nos. 10-2024-0081371, filed on Jun. 21, 2024, and 10-2025-0070014, filed on May 28, 2025, in the Korean Intellectual Property Office, the disclosures of which are incorporated by reference herein in their entireties.

### BACKGROUND

### 1. Field

Some embodiments of the present disclosure relate to a camera assembly.

### 2. Description of Related Art

Embedded systems are control systems operating camera devices by using a processor embedded in various electronic products or devices to perform a predetermined specific function. Embedded systems have basic computing power suitable for the purpose of camera devices by using a processor and a memory embedded therein and perform a control operation by utilizing an application suitable for the purpose.

Embedded systems may be connected to camera assemblies to perform various control operations of a camera by using an application. In addition, embedded systems may be operated based on artificial intelligence (AI) to perform various control operations of cameras in real time and may obtain and classify image data through the cameras.

In this regard, a circuit board kit with an embedded system may be disposed inside a camera assembly, a circuit board may be disposed at an appropriate location inside the camera assembly, and the circuit board may be connected to a camera module to drive the camera module by using an application connected to the camera module.

However, the circuit board may be easily damaged by an external impact, moisture, and foreign substances, and thus, a structure capable of protecting the circuit board disposed inside the camera assembly is required. In addition, when the circuit board is disposed inside the camera assembly, a structure capable of dissipating heat generated from the circuit board is required.

### SUMMARY

Some embodiments of the present disclosure may solve the above-described problems and/or other problems.

According to some embodiments of the present disclosure, a camera assembly may be provided and include a mounting structure of a circuit board including a computing device controlling a camera.

According to some embodiments of the present disclosure, a camera assembly may be provided and include: a camera; a base connected to the camera; a circuit board accommodated by the base; a heat sink on the circuit board; a rubber pad between the base and the heat sink; and a first thermal pad between and in contact with the circuit board and the heat sink, wherein the circuit board is sealed from an outside of the camera assembly by the heat sink and the rubber pad.

According to some embodiments of the present disclosure, the base includes a recess, wherein the circuit board is in the recess, wherein the heat sink is configured to close an open part of the recess to define, with the recess, a sealing space, and wherein the circuit board is in the sealing space.

According to some embodiments of the present disclosure, the camera assembly further includes a storage in the sealing space, the storage including memory.

According to some embodiments of the present disclosure, the camera assembly further includes a second thermal pad between and in contact with the storage and the heat sink.

According to some embodiments of the present disclosure, the camera assembly further includes: a first electrical connector in the recess; and a second electrical connector electrically connected to the circuit board, the storage, and the first electrical connector, wherein the first electrical connector is on a surface of the base that defines the recess, and wherein the first electrical connector and the second electrical connector are connected to the camera.

According to some embodiments of the present disclosure, a surface of the heat sink includes a waterproof material.

According to some embodiments of the present disclosure, the camera assembly further includes a blower on one side of the heat sink.

According to some embodiments of the present disclosure, the base includes, at respective sides of the base, a first vent and a second vent, wherein the first vent and the second vent face each other in a blowing direction of the blower, and wherein the first vent is configured to discharge air, blown from the blower, in the blowing direction to an outside of camera assembly, and the second vent is configured introduce external air into the camera assembly in the blowing direction.

According to some embodiments of the present disclosure, each of the first vent and the second vent includes a mesh structure.

According to some embodiments of the present disclosure, the heat sink includes at least one heat dissipation plate that extends in the blowing direction.

According to some embodiments of the present disclosure, the at least one heat dissipation plate of the heat sink is communicatively connected to the outside of the camera assembly through the first vent and the second vent.

According to some embodiments of the present disclosure, the at least one heat dissipation plate is a plurality of heat dissipation plates that are spaced apart from each other in a direction crossing the blowing direction.

According to some embodiments of the present disclosure, the first vent and the second vent are in corner portions of an edge of the base in a vertical direction of the camera assembly.

According to some embodiments of the present disclosure, the camera assembly further includes a base cover, wherein the base cover is on a side of the base that faces away from the circuit board and the heat sink.

According to some embodiments of the present disclosure, the heat sink has a varying thickness.

According to some embodiments of the present disclosure, a first thickness of a first part of the heat sink overlapping with the circuit board is greater than a second thickness of a second part of the heat sink overlapping with the storage.

According to some embodiments of the present disclosure, a height of the circuit board is less than a height of the storage.

According to some embodiments of the present disclosure, a camera assembly may be provided and include: a camera; a base connected to the camera; a circuit board accommodated by the base; a heat sink on the circuit board; and a first thermal pad between and in contact with the circuit board and the heat sink, wherein the heat sink is configured to connect to the base to seal the circuit board from an outside of the camera assembly.

According to some embodiments of the present disclosure, the base includes a recess, wherein the circuit board is in the recess, wherein the heat sink is configured to close an open part of the recess to define, with the recess, a sealing space, and wherein the circuit board is in the sealing space.

According to some embodiments of the present disclosure, a camera assembly may be provided and include: a camera; a base connected to the camera; a circuit board accommodated by the base; a heat sink on the circuit board; a first thermal pad between and in contact with the circuit board and the heat sink; and a blower on one side of the heat sink, wherein the base includes, at respective sides of the base, a first vent and a second vent, wherein the first vent is configured to discharge air in a blowing direction of the blower to an outside of camera assembly in a case where the air is blown from the blower, and the second vent is configured introduce external air into the camera assembly in the blowing direction, and wherein the heat sink includes at least one heat dissipation plate that extends in the blowing direction between the first vent and the second vent.

Additional aspects will be set forth in part in the description which follows and, in part, will be apparent from the description, or may be learned by practice of the presented example embodiments of the disclosure.

Other aspects, features, and advantages of the present disclosure will become more apparent from the detailed description, the claims, and the drawings.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a perspective view of a camera assembly according to an embodiment;

FIG. 2 is a side view of a camera assembly according to an embodiment;

FIG. 3 is an exploded perspective view of a camera assembly according to an embodiment;

FIG. 4 is a diagram of the camera assembly viewed in a direction A of FIG. 3; and

FIG. 5 is a cross-sectional view of the camera assembly taken along a line I-I′ of FIG. 4.

### DETAILED DESCRIPTION

Reference will now be made in detail to non-limiting example embodiments of the present disclosure, examples of which are illustrated in the accompanying drawings, wherein like reference numerals refer to like elements throughout. In this regard, embodiments of the present disclosure may have different forms and should not be construed as being limited to the descriptions set forth herein. Accordingly, example embodiments are merely described below, by referring to the figures, to explain example aspects of the present disclosure. As used herein, the term “and/or” includes any and all combinations of one or more of the associated listed items. Expressions such as “at least one of,” when preceding a list of elements, modify the entire list of elements and do not modify the individual elements of the list.

Embodiments of the present disclosure may have various modifications thereto, and thus particular example embodiments will be illustrated in the drawings and described in detail below. It should be understood, however, that the example embodiments are not intended to limit the present disclosure, and should be understood that embodiments of the present disclosure include all changes, equivalents, and alternatives falling within the spirit and scope of the present disclosure. To describe aspects of the present disclosure, the same component, even when shown in different embodiments, will be denoted by the same reference numeral.

Hereinafter, non-limiting example embodiments of the present disclosure will be described in detail with reference to the accompanying drawings, and in description with reference to the drawings, the same or corresponding components are given the same reference numerals, and redundant description thereto may be omitted.

In the following description, terms such as “first,” “second,” etc., have been used to distinguish one component from other components, and not to limit the components.

In the following description, singular forms include plural forms unless apparently indicated otherwise contextually.

In the drawings, the size of components may be exaggerated or reduced for convenience of description. For example, the size and thickness of each component shown in the drawings are shown for convenience of description, and thus the present disclosure is not necessarily limited to the illustrations.

In the following description, an x-axis, y-axis, and z-axis are not limited to three axes on the orthogonal coordinate system, and may be interpreted in a broad sense including the same. For example, the x-axis, y-axis, and z-axis may be orthogonal to each other, but may also refer to different directions that are not orthogonal to each other.

According to some embodiments of the present disclosure, a particular process order may be performed differently from the order described. For example, two processes described in succession may be performed substantially simultaneously, or may be performed in an order reverse to the order described.

The terms used herein are used to describe example embodiments, and are not intended to limit the present disclosure.

Herein, it should be understood that the terms “include,” “comprise,” “have,” or the like used herein is to indicate the presence of features, numbers, steps, operations, components, parts, or a combination thereof described in the specifications, and does not preclude the presence or addition of one or more other features, numbers, steps, operations, components, parts, or a combination thereof.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

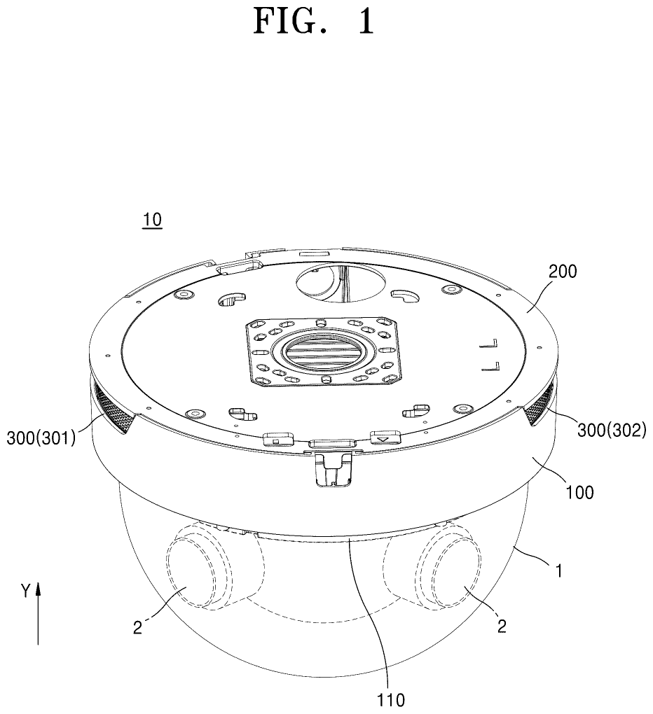

Hereinafter, a camera including a structure for avoiding diffuse reflection of a light source according to an embodiment will be described with reference to FIGS. 1 to 5.

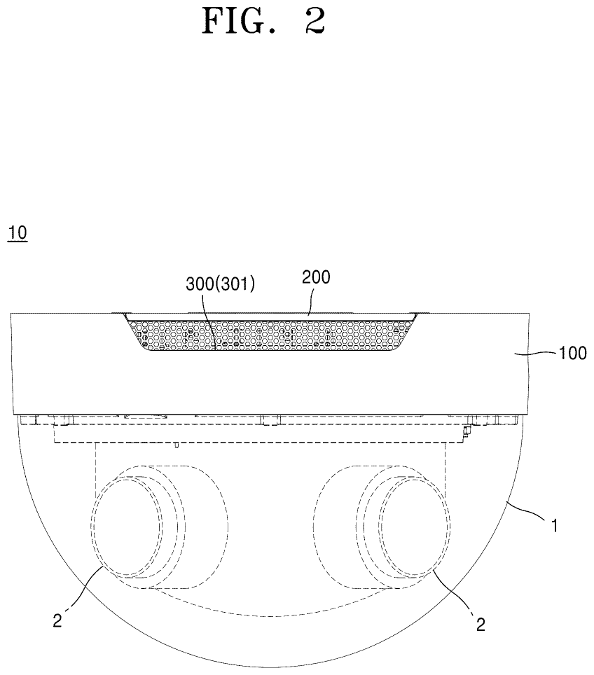

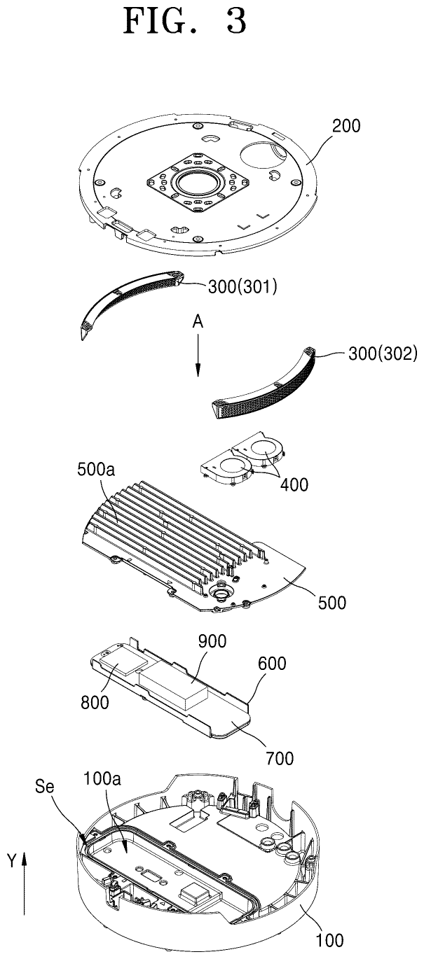

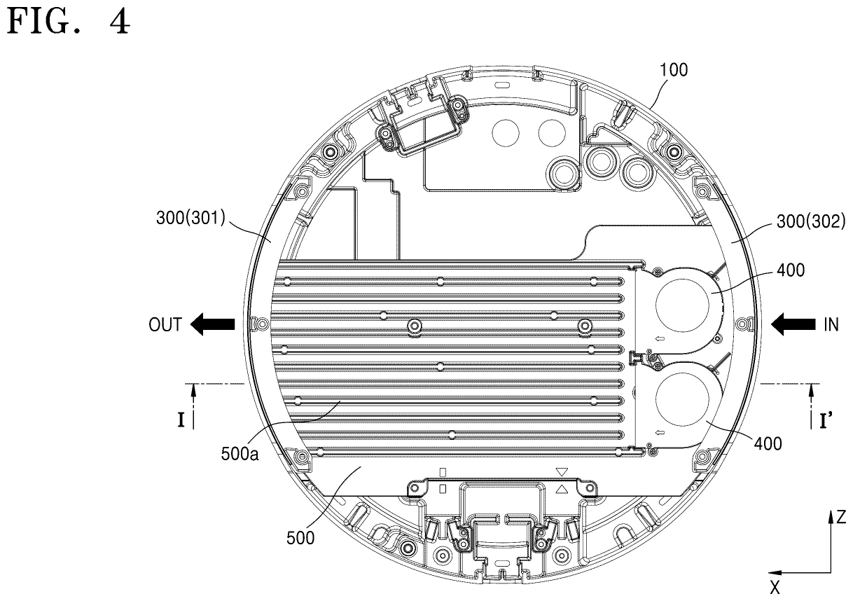

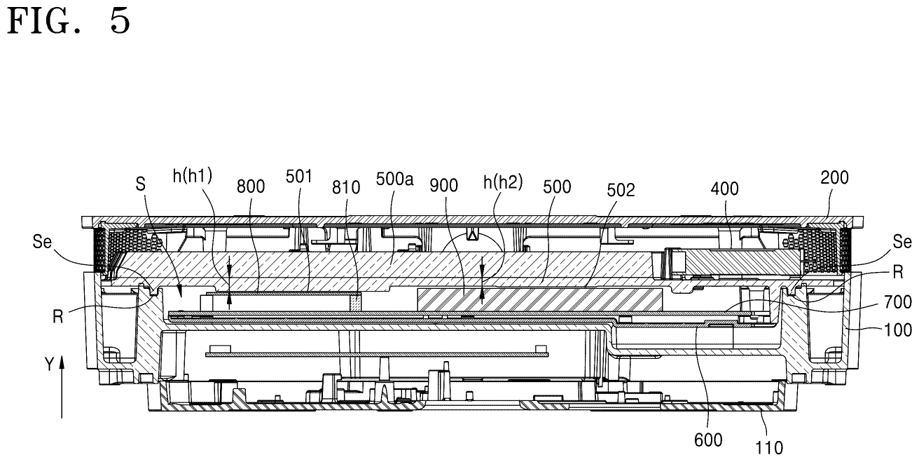

FIG. 1 is a perspective view of a camera assembly according to an embodiment. FIG. 2 is a side view of the camera assembly according to an embodiment. FIG. 3 is an exploded perspective view of the camera assembly according to an embodiment. FIG. 4 is a diagram of the camera assembly viewed in a direction A of FIG. 3. FIG. 5 is a cross-sectional view of the camera assembly taken along a line I-I′ of FIG. 4.

Referring to FIGS. 1 to 5, a camera assembly 10 according to an embodiment may include at least one camera module 2 (e.g., a camera), a base portion 100 (e.g., a base) connected to the camera module 2 and accommodating a circuit board unit 800 (e.g., a circuit board), and a heat sink 500 covering the circuit board unit 800. The circuit board unit 800 may be sealed by the heat sink 500.

More specifically, a recessed portion 100a (e.g., a recess) forming a sealing space S may be formed in the base portion 100, the circuit board unit 800 may be accommodated in the recessed portion 100a, the heat sink 500 may close an open part of the recessed portion 100a to form the sealing space S, and the circuit board unit 800 may be disposed in the sealing space S.

The camera assembly 10 according to the present embodiment may include a camera module 2 and a camera module accommodation portion 1 accommodating the camera module 2. The camera module accommodation portion 1 may be formed to cover the base portion 100 on which the circuit board unit 800 is mounted and the at least one camera module 2. The camera module accommodation portion 1 may include a transparent material, so that the camera module 2 inside the camera module accommodation portion 1 may capture an image outside of the camera assembly 10.

For example, the camera assembly 10 may be a surveillance camera. The surveillance camera may include, for example, a camera for closed-circuit television (CCTV).

The camera module 2 according to the present embodiment may be disposed in a −y-axis direction with respect to the base portion 100. According to some embodiments, a multi-camera structure may be provided in which a plurality of camera modules 2 arranged in a circumferential direction with respect to a center of the base portion 100, the base portion 100 formed in a cylindrical shape.

The base portion 100 may be formed in the cylindrical shape. An opening of the base portion 100 in a Y-axis direction may be covered by a cover portion 200. The cover portion 200 may be formed in a disk shape to cover the circular opening of the base portion 100.

The cover portion 200 may form an inner space of the camera assembly 10 while covering the base portion 100. The heat sink 500 and a blower 400 to be described below may be accommodated in the inner space.

The at least one camera module 2 may be disposed on a base cover 110. The base cover 110 may be disposed on a side of the base portion 100 that faces away from the circuit board unit 800 and the heat sink 500. The at least one camera module 2 may be rotated on the base cover 110 with respect to the center of the base cover 110.

The camera module 2 may operate by a signal applied from the outside. The camera module 2 may include a lens unit (e.g., a least one lens), an imaging device (e.g., an image sensor), and an image processing unit (e.g., at least one processor). The lens unit may accommodate a light source, the imaging device may convert the light source into an electrical signal, and the image processing unit may generate image data by processing the signal generated by the imaging device.

According to the present embodiment, the recessed portion 100a may be recessed in the base portion 100 in the −y-axis direction. The circuit board unit 800 may be disposed in the recessed portion 100a. For example, the circuit board unit 800 may be a computing device. The computing device may be connected to the at least one camera module 2 of the camera assembly 10 to perform various control operations of a camera by using an application. In addition, the computing device may be executed based on artificial intelligence (AI) to perform various control operations of the camera in real time, and obtain and classify image data through the camera. For example, the circuit board unit 800 may be connected to the at least one camera module 2 through a main printed circuit board (PCB). The main control of the camera module 2 may be controlled by the main PCB, and a web driving setting and control of the camera assembly 10 may be performed by the circuit board unit 800.

The computing device may be an additional computing device driving an application connected to the camera module 2, in addition to a control unit controlling the camera module 2.

According to the present embodiment, the circuit board unit 800 may be disposed on in recessed portion 100a of the base portion 100, and may be disposed in the sealing space S sealed by the heat sink 500 covering the recessed portion 100a. The heat sink 500 may seal the recessed portion 100a in which the circuit board unit 800 is located, thereby previously preventing water or foreign substances from entering the sealing space S. The sealing space S may be formed (e.g., defined) by the base portion 100 and the heat sink 500. The sealing space S may be sealed by a sealing portion Se of a structure in which a body of the base portion 100 that defines the recessed portion and a protrusion portion (e.g., a protrusion) of the heat sink 500 are fitted together. The sealing portion Se may improve a sealing force between the base portion 100 and the heat sink 500 through a concave-convex coupling structure between a concave part of the body of the base portion 100, that defines the recessed portion 100a of the base portion 100, and a convex part of the protrusion portion of the heat sink 500.

According to an embodiment, the sealing portion may include a rubber pad R. For example, the sealing portion Se may be between the concave part of the body of the base portion 100, that defines the recessed portion 100a of the base portion 100, and the convex part of the protrusion portion of the heat sink 500, thereby providing sealing between the base portion 100 and the heat sink 500. Accordingly, the sealing structure of the base portion 100 and the heat sink 500 may be further strengthened together with the concave-convex structure of the sealing portion Se.

In addition, the circuit board unit 800, which may be vulnerable to impact, may be disposed in a space surrounded by the base portion 100 and the heat sink 500 without being exposed to the outside, thereby protecting the circuit board unit 800 from external impact that may occur in the camera assembly 10.

According to the present embodiment, a storage device 900 (e.g., a storage) may be further disposed in the sealing space S. The storage device 900 may be connected to the circuit board unit 800, and include a memory storing a program capable of driving a processor of the circuit board unit 800. For example, the storage device 900 may be a solid state drive (SSD).

According to the present embodiment, the circuit board unit 800 and the storage device 900 may be connected to a second connection portion 700 (e.g., a second electrical connector) in the sealing space S. The circuit board unit 800 may be mounted on a circuit board mounting portion 810 (e.g., a circuit board mount), and the circuit board mounting portion 810 may be connected to the second connection portion 700.

The circuit board unit 800 and the storage device 900 may be connected to the second connection portion 700, the second connection portion 700 may be connected to a first connection portion 600 (e.g., a first electrical connector), the first connection portion 600 may be seated on the recessed portion 100a, and the first connection portion 600 and the second connection portion 700 may be connected to the camera module 2. For example, the circuit board unit 800 and the storage device 900 may be electrically connected to the camera module 2 via the second connection portion 700 and the first connection portion 600. For example, the first connection portion 600 may be on a surface of the base portion 100 that defines a bottom of the recessed portion 100a, and the second connection portion 700 may be between the first connection portion 600 and the circuit board unit 800 and the storage device 900.

Referring to FIG. 5, according to the present embodiment, a first thermal pad 501 may be disposed between and in contact with the circuit board unit 800 and the heat sink 500. In addition, a second thermal pad 502 may be disposed between and in contact with the storage device 900 and the heat sink 500. A thermal pad may be a pad having thermal transfer power. Accordingly, the first thermal pad 501 and the second thermal pad 502 may transfer heat generated from the circuit board unit 800 and the storage device 900 to the heat sink 500.

Specifically, the sealing space S is a sealed space such that no convection may occur in the sealing space S. Accordingly, heat may be dissipated through conduction through the first thermal pad 501 and the second thermal pad 502 disposed in the sealing space S. Therefore, the first thermal pad 501 and the second thermal pad 502 may allow the circuit board unit 800 and the storage device 900 to contact the heat sink 500, thereby dissipating heat to the outside of the sealing space S through conduction.

Referring to FIG. 5, according to the present embodiment, when the circuit board unit 800 and the storage device 900 have different heights from each, a height h1 of a part of the heat sink 500 overlapping with the circuit board unit 800 and a height h2 of a part of the heat sink 500 overlapping with the storage device 900 may be different from each other while thicknesses of the first thermal pad 501 and the second thermal pad 502 in the Y-axis direction remain the same. This is because the thermal conductivity decreases as the thickness of a thermal pad increases, the thicknesses of the first thermal pad 501 and the second thermal pad 502 remain the same, and a difference in the thickness in the Y-axis direction between the circuit board unit 800 and the storage device 900 corresponds to a height difference of the heat sink 500, thereby securing the heat transfer performance of the camera assembly 10. For example, in a case where the storage device 900 has a greater thickness in the Y-axis direction than a thickness of the circuit board unit 800 in the Y-axis direction, the height h1 of the part of the heat sink 500 overlapping with the circuit board unit 800 may be greater than the height h2 of the part of the heat sink 500 overlapping with the storage device 900. According to embodiments, the height h1 and the height h2 may be thicknesses of a portion of the heat sink 500 on which the heat dissipation plate 500a is provided, or may be entire thicknesses of the heat sink 500 (e.g., including both the portion and the heat dissipation plate 500a).

The heat sink 500 may dissipate heat to the outside of the camera assembly 10 through at least one heat dissipation plate 500a of the heat sink 500. To this end, the heat dissipation plate 500a of the heat sink 500 may dissipate heat generated by the circuit board unit 800 and/or the storage device 900 to the outside through a structure in which the at least one heat dissipation plate 500a is communicatively connected to the outside of the camera assembly 10 through a first vent portion 301 (e.g., a first vent) and a second vent portion 302 (e.g., a second vent). According to the present embodiment, a surface portion of the heat sink 500 may include a waterproof material. In addition, the blower 400 may be disposed on one side of the heat sink 500.

Referring to FIG. 4, the first vent portion 301 and the second vent portion 302 may be disposed in opposite sides of the base portion 100. The first vent portion 301 and the second vent portion 302 may each include a mesh structure to perform a venting function. The first vent portion 301 and the second vent portion 302 may be disposed along corner portions of the edge of the base portion 100 in the Y-axis direction, and may be formed in an arc shape, and thus ventilation of the internal space of the camera assembly 10 may be possible through the first vent portion 301 and the second vent portion 302.

The first vent portion 301 and the second vent portion 302 may be disposed to face each other in a blowing direction of the blower 400. That is, referring to FIG. 4, the blowing direction of the blower 400 may be from an “IN” direction to an “OUT” direction, that is, an X-axis direction. Air blown through the blower 400 may be discharged to the outside through the first vent portion 301 in the “OUT” direction. Simultaneously, external air may be introduced into the camera assembly 10 through the second vent portion 302 in the blowing direction of the blower 400. The blower 400 may dissipate heat generated from the heat sink 500 to the outside by circulating air inside the camera assembly 10. Portions of the base portion defining the first vent portion 301 and the second vent portion 302 may include plastic. Accordingly, the weight of the camera assembly 10 may be reduced and heat may be more effectively dissipated through the first vent portion 301 and the second vent portion 302 that are each defined by a light material.

A heat dissipation function of the heat sink 500 may be adjusted according to the weight and/or volume of the heat sink 500. That is, when the weight of the heat sink 500 increases, heat dissipation performance may be improved. In addition, as the volume of the heat sink 500 increases, a heat dissipation function may be improved. For example, referring to FIG. 5, as a thickness h of the heat sink 500 increases, the heat dissipation function of the heat sink 500 may be improved. According to some embodiments, the heat sink 500 may include varying thicknesses (e.g., the first height h1 and the second height h2).

According to the present embodiment, a longitudinal direction (e.g., an extending direction) of the heat dissipation plate 500a of the heat sink 500 may be formed in a direction parallel to the X-axis direction. That is, the longitudinal direction of the heat dissipation plate 500a of the heat sink 500 may be formed in a direction parallel to a direction in which the first vent portion 301 and the second vent portion 302 face each other, and thus the air blown through the blower 400 may be effectively discharged to the outside through the first vent portion 301 along the space between the heat dissipation plates 500a. According to embodiments, a plurality of the heat dissipation plates 500a may be provided such as to extend in the X-axis direction while being spaced apart from each other at equal intervals in the Z-axis direction. Accordingly, the heat dissipation effect may be maximized by maximizing the surface area in which the heat dissipation plates 500a are in contact with air. In addition, the blower 400 may increase the contact area between the heat dissipation plates 500a and the air by causing the air to flow between the plurality of heat dissipation plates 500a.

The blower 400 may be disposed on a side portion of the heat sink 500, as opposed to a central portion of the heat sink 500. The blower 400 may be disposed at a side portion of the heat dissipation plate 500a of the heat sink 500, and may be disposed closer to the second vent portion 302 than the first vent portion 301. For example, the blower 400 may be disposed between the heat dissipation plates 500a and the second vent portion 302, and the heat dissipation plates 500a may be between the blower 400 and the first vent portion 301. The blower 400 may be formed to blow air from the side portion of the heat dissipation plates 500a of the heat sink 500 so that the blown air passes between the heat dissipation plates 500a. Accordingly, heat generated from the heat dissipation plates 500a may pass through the first vent portion 301 with the blown air and be dissipated to the outside of the camera assembly 10. The blower 400 may include a waterproof material to previously prevent moisture from entering the blower 400.

According to the present embodiment, the cover portion 200 and the heat sink 500 may be detached from the base portion 100. The circuit board unit 800 may also be detached from the circuit board mounting portion 810 in the recessed portion 100a. Accordingly, a computing device desired by a user of the camera assembly 10 may be inserted into the camera assembly 10.

Specifically, to replace the circuit board unit 800, the computing device desired by the user may be mounted in the camera assembly 10 through a simple process of removing the cover portion 200 and the heat sink 500 from the base portion 100, removing the circuit board unit 800 from the circuit board mounting portion 810, mounting a new circuit board unit on the circuit board mounting portion 810, and again mounting the heat sink 500 and the cover portion 200 to the base portion 100 in order.

Non-limiting example embodiments of the present disclosure have been described above with reference to the accompanying drawings. It would be fully understood by one of ordinary skill in the art that various modifications and other equivalent embodiments are possible from the example embodiments, and that such various modifications and equivalent embodiments are included within the spirit and scope of the present disclosure.

Specific technical aspects described above with respect to the embodiments are examples, and do not limit the technical scope of the embodiments. In order to briefly and clearly describe the description of the present disclosure, the description of general techniques and configurations may be omitted.

Connections of lines or connection members between components shown in the drawings are illustrative of functional connections and/or physical or circuit connections, and in practice, may be expressed as alternative or additional various functional connections, physical connections, or circuit connections. In addition, the components may be omitted from embodiments of the present disclosure unless otherwise stated to the contrary.

A designator “the” or similar designators described in the description and the claims may refer to both singular and plural, unless otherwise specifically limited.

The camera assembly according to an embodiment employs the sealing structure that physically protects the circuit board disposed inside the camera assembly and has the heat dissipation function that discharges heat generated from the circuit board by using the heat sink.

However, effects of embodiments of the present disclosure are not limited to the above-described effects, and other effects not mentioned of embodiments of the present disclosure may be clearly understood from the description above.

It should be understood that embodiments described herein should be considered in a descriptive sense only and not for purposes of limitation. Descriptions of features or aspects within each embodiment of the present disclosure should typically be considered as available for other similar features or aspects in other embodiments of the present disclosure. While one or more example embodiments have been described with reference to the figures, it will be understood by one of ordinary skill in the art that various changes in form and details may be made therein without departing from the spirit and scope of the present disclosure.

What is claimed is:

1. A camera assembly comprising:
a camera;
a base connected to the camera;
a circuit board accommodated by the base;
a heat sink on the circuit board;
a rubber pad between the base and the heat sink; and
a first thermal pad between and in contact with the circuit board and the heat sink,
wherein the circuit board is sealed from an outside of the camera assembly by the heat sink and the rubber pad.

2. The camera assembly of claim 1, wherein the base includes a recess,
wherein the circuit board is in the recess,
wherein the heat sink is configured to close an open part of the recess to define, with the recess, a sealing space, and
wherein the circuit board is in the sealing space.

3. The camera assembly of claim 2, further comprising a storage in the sealing space, the storage including memory.

4. The camera assembly of claim 3, further comprising a second thermal pad between and in contact with the storage and the heat sink.

5. The camera assembly of claim 3, further comprising:
a first electrical connector in the recess; and
a second electrical connector electrically connected to the circuit board, the storage, and the first electrical connector,
wherein the first electrical connector is on a surface of the base that defines the recess, and
wherein the first electrical connector and the second electrical connector are connected to the camera.

6. The camera assembly of claim 1, wherein a surface of the heat sink comprises a waterproof material.

7. The camera assembly of claim 1, further comprising a blower on one side of the heat sink.

8. The camera assembly of claim 7, wherein the base comprises, at respective sides of the base, a first vent and a second vent,
wherein the first vent and the second vent face each other in a blowing direction of the blower, and
wherein the first vent is configured to discharge air, blown from the blower, in the blowing direction to an outside of camera assembly, and the second vent is configured introduce external air into the camera assembly in the blowing direction.

9. The camera assembly of claim 8, wherein each of the first vent and the second vent comprises a mesh structure.

10. The camera assembly of claim 8, wherein the heat sink comprises at least one heat dissipation plate that extends in the blowing direction.

11. The camera assembly of claim 10, wherein the at least one heat dissipation plate of the heat sink is communicatively connected to the outside of the camera assembly through the first vent and the second vent.

12. The camera assembly of claim 10, wherein the at least one heat dissipation plate is a plurality of heat dissipation plates that are spaced apart from each other in a direction crossing the blowing direction.

13. The camera assembly of claim 8, wherein the first vent and the second vent are in corner portions of an edge of the base in a vertical direction of the camera assembly.

14. The camera assembly of claim 1, further comprising a base cover,
wherein the base cover is on a side of the base that faces away from the circuit board and the heat sink.

15. The camera assembly of claim 1, wherein the heat sink has a varying thickness.

16. The camera assembly of claim 1, wherein a first thickness of a first part of the heat sink overlapping with the circuit board is greater than a second thickness of a second part of the heat sink overlapping with the storage.

17. The camera assembly of claim 16, wherein a height of the circuit board is less than a height of the storage.

18. A camera assembly comprising:
a camera;
a base connected to the camera;
a circuit board accommodated by the base;
a heat sink on the circuit board; and
a first thermal pad between and in contact with the circuit board and the heat sink,
wherein the heat sink is configured to connect to the base to seal the circuit board from an outside of the camera assembly.

19. The camera assembly of claim 18, wherein the base includes a recess,
wherein the circuit board is in the recess,
wherein the heat sink is configured to close an open part of the recess to define, with the recess, a sealing space, and
wherein the circuit board is in the sealing space.

20. A camera assembly comprising:
a camera;
a base connected to the camera;
a circuit board accommodated by the base;
a heat sink on the circuit board;
a first thermal pad between and in contact with the circuit board and the heat sink; and
a blower on one side of the heat sink,
wherein the base comprises, at respective sides of the base, a first vent and a second vent,
wherein the first vent is configured to discharge air in a blowing direction of the blower to an outside of camera assembly in a case where the air is blown from the blower, and the second vent is configured introduce external air into the camera assembly in the blowing direction, and
wherein the heat sink comprises at least one heat dissipation plate that extends in the blowing direction between the first vent and the second vent.
